(19) United States
(12) Patent Application Publication
(10) Pub. No.: US 2011/0291132 A1
(43) Pub. Date: Dec. 1, 2011

(54) LIGHT-EMITING DEVICE WITH IMPROVED COLOR RENDERING INDEX

(76) Inventors: Fang-Chang LIU, Miaoli County (TW); Kuan-Ping Lee, Iaoyuan County (TW)

(21) Appl. No.: 12/790,496

(22) Filed: May 28, 2010

(51) Int. Cl. H01L 33/50

(52) U.S. Cl. 257/98; 257/E33.061

(57) ABSTRACT

A light-emitting device (LED) is disclosed. The LED includes a carrier substrate having a blue light emitter thereon. A layer containing a fluorescent material is on the blue light emitter. An encapsulant is disposed around the blue light emitter. Pigments are suspended between an outer surface of the encapsulant and the blue light emitter.

### BACKGROUND OF THE INVENTION

1. Field of the Invention

The invention relates to a light-emitting device (LED) and more particularly to LEDs capable of improving color rendering index (CRI).

2. Description of the Related Art

Light-emitting devices (LEDs) are solid-state light sources and have been known for years. The LEDs are based on the recombination of electron-hole pairs in a pn-junction in a semiconductor material which is forward-biased. Advantages of LEDs compared with traditional lamps are lower power consumption and longer lifespan, and therefore the white light LED has become one of the most popular illuminating devices used.

Such a white light LED can be obtained by mixing red, green, and blue lights using a combination of a red light LED chip (or die), a green light LED chip, and a blue light LED chip to form the white light LED. However, the above three-in-one white light LED is expensive because it requires three LED chips for different emitted lights. Moreover, CRI performance is reduced due to different light-emitting efficiencies for each of the three LED chips.

Alternatively, a white light LED has been developed using a combination of a blue light LED chip with a fluorescent material, such as a phosphor material. The blue light passes through the phosphor material, such that the combination of blue light LED chip and the fluorescent material produces a white light. However, the phosphor material typically dominates the color temperature of the light emitted from the LED chip, such that CRI performance of the white light LED is reduced. In order to further improve CRI performance of the white light LED, an additional LED chip, such as a red light LED chip is disposed adjacent to the blue light LED chip. The additional LED chip is employed for specific color compensation of light, thereby enhancing the intensity of the specific light wavelength. As a result, CRI performance of the white light LED is improved. Although this approach may improve CRI performance of the white light LED, the manufacturing cost, power consumption, and the total volume of the white light LED are increased due to the additional LED chip.

Accordingly, there is a need to develop a novel LED capable of improving CRI performance while addressing the above problems.

### BRIEF SUMMARY OF THE INVENTION

A detailed description is given in the following embodiments with reference to the accompanying drawings. A light-emitting device (LED) is provided. An embodiment of a light-emitting device comprises a carrier substrate having a blue light emitter thereon. A layer containing a fluorescent material is on the blue light emitter. An encapsulant is disposed around the blue light emitter. Pigments are suspended between an outer surface of the encapsulant and the blue light emitter.

Another embodiment of a light-emitting device comprises a carrier substrate having a blue light emitter thereon. A layer containing a fluorescent material is on the blue light emitter. A vehicle is disposed on the layer containing the fluorescent material. An encapsulant covers the blue light emitter, the layer containing the fluorescent material, and the vehicle. Pigments are suspended in the vehicle.

Yet another embodiment of a light-emitting device comprises a carrier substrate having a blue light emitter thereon. A layer containing a fluorescent material is on the blue light emitter. An optical lens covers the blue light emitter and the layer containing the fluorescent material. Pigments are suspended in the optical lens.

### BRIEF DESCRIPTION OF DRAWINGS

The invention can be more fully understood by reading the subsequent detailed description and examples with references made to the accompanying drawings, wherein:

FIGS. 1 to 3 are cross sections of various exemplary embodiments of an LED according to the invention.

### DETAILED DESCRIPTION OF INVENTION

The following description is of the best-contemplated mode of carrying out the invention. This description is provided for the purpose of illustrating the general principles of the invention and should not be taken in a limiting sense. The scope of the invention is best determined by reference to the appended claims.

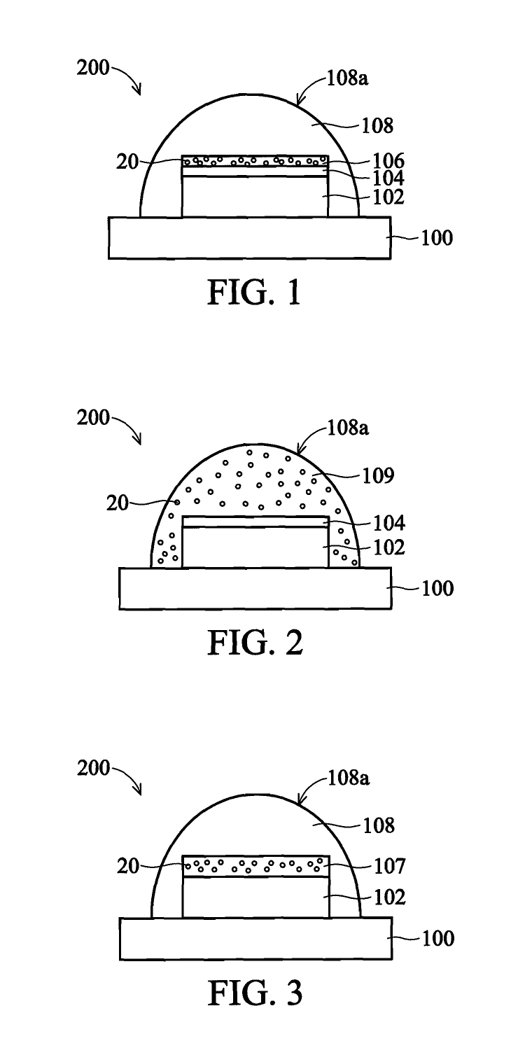

Referring to FIG. 1, which illustrates a cross section of an exemplary embodiment of an LED according to the invention. The LED 200, such as a white light LED, comprises a carrier substrate 100. The carrier substrate 100 may be a semiconductor or ceramic substrate or other suitable package substrate well known in the art. In one embodiment, the carrier substrate 100 is a silicon substrate and may contain a variety of elements, including, for example, transistors, resistors, and other semiconductor elements well known in the art. In order to simplify the diagram, the variety of elements is not depicted.

A light emitter 102, such as a blue light emitter or a blue light-emitting diode, is on the carrier substrate 100 and is electrically connected thereto by a conventional wire bonding process through wiring lines or by a flip chip method through bumps.

A layer 104 containing a fluorescent material (hereinafter is also referred as a fluorescent material containing layer) is coated on a top surface of the blue light emitter 102. Typically, the fluorescent material containing layer 104 is formed by mixing phosphor particles with a resin or glue, such as acrylic adhesive (i.e. AB Glue). The blue light emitted from the underlying blue light emitter 102 passes through the fluorescent material containing layer 104 with red and green phosphor materials, such that the combination of blue, red, and green lights produces a white light.

An encapsulant 108 is disposed around the blue light emitter 102 and may cover the top surface of the carrier substrate 100, the entire blue light emitter 102, and the fluorescent material containing layer 104. In one embodiment, the encapsulant 108 is an optical lens comprising epoxy or glue and is formed by molding.

In particular, in order to further improve the CRI performance of the white light LED 200, pigments 20 are suspended between an outer surface 108a of the encapsulant 108 and the blue light emitter 102. The pigment is a material that changes the color of reflected or transmitted light as the result of wavelength-selective absorption. This physical process differs from fluorescence, phosphorescence, and other forms of luminescence, in which a material emits light. The pigment is insoluble in the vehicle, resulting in a suspension. Therefore, pigments are usually added to a vehicle (or binder), a relatively neutral or colorless material that suspends the pigments and gives the mixture its adhesion. In the embodiment, the pigments 20 may comprise at least one of red, green, and blue, brown, cyan, violet, magenta, and yellow pigments. Namely, the pigments 20 may have a single color or be composed of a mixture of different color pigments. In one embodiment, the Pigments 20 may have a single color, such as red, and be added to a vehicle 106, such as a resin or glue comprising an acrylic adhesive, such that the pigments 20 are suspended in the vehicle 20. Moreover, the vehicle 106 is disposed on the fluorescent material containing layer 104 and covered by the encapsulant 108. Additionally, it is noted that if the fraction of a weight of the pigments 20 to a total weight of the pigments 20, the vehicle 106, and the fluorescent material (which is in the fluorescent material containing layer 104) is too high, the emitted light is decayed seriously. Accordingly, in the embodiment, the fraction of a weight of the pigments 20 to a total weight of the pigments 20, the vehicle 106, and the fluorescent material is less than 30%. Preferably, the fraction of a weight of the pigments 20 to a total weight of the pigments 20, the vehicle 106, and the fluorescent material is less than 20%.

The pigments 20 within the vehicle 106, which filters undesired light wavelengths, is employed for specific color compensation of light, thereby enhancing the intensity of the specific light wavelength (e.g. red light). As a result, CRI performance of the white light LED 200 is improved. Note that the pigments 20 within the vehicle 106 can be determined by design demands and is not limited to the red pigments. In another embodiment, the pigments 20 within the vehicle 106 may be composed of pigments with different colors.

Referring to FIG. 2, which illustrates a cross section of another exemplary embodiment of an LED according to the invention. Elements in FIG. 2 that are the same as those in FIG. 1 are labeled with the same reference numbers as in FIG. 1 and are not described again for brevity. Unlike the embodiment shown in FIG. 1, the pigments 20 is added to an encapsulant, for example, an optical lens material comprising an epoxy or glue, such that the pigments are suspended therein. In the embodiment, the pigments 20 is mixed with the encapsulant to form an optical lens 109 containing pigments 20 that covers the top surface of the carrier substrate 100, the blue light emitter 102, and the fluorescent material containing layer 104. Moreover, the fraction of a weight of the pigments 20 to a total weight of the pigments 20, the optical lens 109 (i.e. the encapsulant), and the fluorescent material is less than 30%. Preferably, the fraction of a weight of the pigments 20 to a total weight of the pigments 20, the optical lens 109, and the fluorescent material is less than 20%.

Referring to FIG. 3, which illustrates a cross section of further another exemplary embodiment of an LED according to the invention. Elements in FIG. 3 that are the same as those in FIG. 1 are labeled with the same reference numbers as in FIG. 1 and are not described again for brevity. Unlike the embodiment shown in FIG. 1, the pigments 20 are added to a fluorescent material containing layer 107. In the embodiment, the pigments 20 are mixed with similar or the same glue or resin as that used in the fluorescent material containing layer 104 (as shown in FIG. 1) to form a fluorescent material containing layer 107 having pigments 20 suspended therein that is disposed on the blue Light emitter 102. Moreover, the fraction of a weight of the pigments 20 to a total weight of the pigments 20 and the fluorescent material containing layer 107 is less than 30%. Preferably, the fraction of a weight of the pigments 20 to a total weight of the pigments 20 and the fluorescent material containing layer 107 is less than 20%.

The LED 200 of the aforementioned embodiments may be applied in various electronic devices for illumination, such as projectors or micro-projectors.

According to the aforementioned embodiments, the pigments are suspended between the outer surface of the encapsulant and the blue light emitter to enhance CRI performance of the white light LED. Compared to the conventional white light LED, which uses an additional LED chip for enhancing CRI performance thereof, the white light LED having pigments therein can have relatively low manufacturing cost and power consumption and relatively small total volume. Additionally, since the pigments have higher transmittance than that of the phosphor particles within the fluorescent material containing layer disposed on the blue light emitter, illumination performance of the white light LED can be substantially maintained while still enhancing CRI performance thereof.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A light-emitting device, comprising:
a carrier substrate;
a blue light emitter on the carrier substrate;
a layer containing a fluorescent material on the blue light emitter;
an encapsulant disposed around the blue light emitter; and
pigments suspended between an outer surface of the encapsulant and the blue light emitter.

2. The light-emitting device of claim 1, wherein the encapsulant comprises an optical lens that comprises an epoxy or glue.

3. The light-emitting device of claim 1, further comprising a vehicle disposed on the fluorescent material containing layer and the pigments are added to the vehicle.

4. The light-emitting device of claim 3, wherein the vehicle is a glue comprising an acrylic adhesive.

5. The light-emitting device of claim 3, wherein the vehicle is a resin.

6. The light-emitting device of claim 3, wherein the fraction of a weight of the pigments to a total weight of the pigments, the vehicle, and the fluorescent material is less than 30%.

7. The light-emitting device of claim 3, wherein the fraction of a weight of the pigments to a total weight of the pigments, the vehicle, and the fluorescent material is less than 20%.

8. The light-emitting device of claim 1, wherein the pigments are added to the encapsulant.

9. The light-emitting device of claim 1, wherein the pigments are added the fluorescent material containing layer.

10. The light-emitting device of claim 1, wherein the fraction of a weight of the pigments to a total weight of the pigments and the fluorescent material containing layer is less than 30%.

11. The light-emitting device of claim 1, wherein the fraction of a weight of the pigments to a total weight of the pigments and the fluorescent material containing layer is less than 20%.

12. The light-emitting device of claim 1, wherein the fraction of a weight of the pigments to a total weight of the pigments, the encapsulant, and the fluorescent material is less than 30%.

13. The light-emitting device of claim 1, wherein the fraction of a weight of the pigments to a total weight of the pigments, the encapsulant, and the fluorescent material is less than 20%.

14. The light-emitting device of claim 1, wherein the pigments material comprises at least one of red, green, blue, brown, cyan, violet, magenta, and yellow pigments.

15. A light-emitting device, comprising:
a carrier substrate;
a blue light emitter on the carrier substrate;
a layer containing a fluorescent material on the blue light emitter;
a vehicle disposed on the layer containing the fluorescent material;
an encapsulant covering the blue light emitter, the layer containing the fluorescent material, and the vehicle; and
pigments suspended in the vehicle.

16. The light-emitting device of claim 15, wherein the vehicle is a glue or resin.

17. The light-emitting device of claim 15, wherein the fraction of a weight of the pigments to a total weight of the pigments, the vehicle, and the fluorescent material is less than 30%.

18. A light-emitting device, comprising:
a carrier substrate;
a blue light emitter on the carrier substrate;
a layer containing a fluorescent material on the blue light emitter;
an optical lens covering the blue light emitter and the layer containing the fluorescent material; and
pigments suspended in the optical lens.

19. The light-emitting device of claim 18, wherein the optical lens comprises an epoxy or glue.

20. The light-emitting device of claim 19, wherein the fraction of a weight of the pigments to a total weight of the pigments, the optical lens, and the fluorescent material is less than 30%.
